(19) United States
(12) Patent Application Publication
(10) Pub. No.: US 2010/0144119 A1
(43) Pub. Date: Jun. 10, 2010

(54) METHOD OF PRODUCING BONDED WAFER

(75) Inventors: Tatsumi Kusaba, Minato-ku (JP); Akihiko Endo, Minato-ku (JP)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: SUMCO CORPORATION, Tokyo (JP)

(21) Appl. No.: 12/631,478

(22) Filed: Dec. 4, 2009

(30) Foreign Application Priority Data
Dec. 8, 2008 (JP) 2008-311813

(51) Int. Cl. H01L 21/762

(52) U.S. Cl. 438/459; 257/E21.567

(57) ABSTRACT

In the production of a bonded wafer, a wafer for active layer after a heat treatment for bonding reinforcement followed by bonding is thinned to a given thickness by a surface polishing or an etching and then a wafer for support layer is subjected to both a minor-surface beveling and a terrace processing simultaneously.

### BACKGROUND OF THE INVENTION

1. Field of the Invention

This invention relates to a method of producing a bonded wafer, and more particularly to the production of a bonded wafer having an excellent quality in a terrace of a wafer for active layer at low cost under the reduction of steps.

2. Description of the Related Art

As a typical production method of a bonded wafer, there are known a method wherein a silicon wafer having an oxide film (insulating film) is bonded to another silicon wafer and then one side of the resulting bonded wafer is ground and polished to form SOI layer (grinding-polishing method), a method wherein oxygen ions are implanted into an interior of a silicon wafer and thereafter a high-temperature annealing is conducted to form a buried oxide film in the silicon wafer and then an upper portion of the oxide film is rendered into SOI layer (SIMOX), a method wherein ions of hydrogen or the like are implanted into a surface layer portion of a silicon wafer for SOI layer (wafer for active layer) to form an ion implanted layer and thereafter the wafer is bonded to a silicon wafer for support substrate and then the resulting bonded wafer is exfoliated at the ion implanted layer through a heat treatment to form SOI layer (smart cut (Registered Trademark) method), and so on.

When a bonded wafer is produced by the above bonding method, it is required to conduct a treatment for removing an unadhered portion unavoidably left on a peripheral portion of the bonded wafer, or a treatment for the formation of a terrace portion. Because such unadhered portion causes the occurrence of particles due to exfoliation or disengagement unless it is removed previously.

Moreover, a factor of forming the unadhered portion is considered to be a face drop of a beveled portion or a mirror-surface polished portion in the wafer. The width of the unadhered portion is usually about 0.5 to 3.0 mm although it depends on the wafer shape.

Heretofore, there are proposed various methods for removing the unadhered portion, or various methods for forming the terrace portion as described below:

(1) A method in which a bonded wafer is subjected to a surface grinding and thereafter taped so as to leave an outer peripheral portion thereof and then the exposed outer peripheral portion is removed by etching;

(2) A method in which an outer peripheral portion of a bonded wafer is thinned to 10 to 100 μm by grinding and then removed by etching (JP-A-2000-223452);

(3) A method in which a groove is formed on an outer peripheral portion of a bonded wafer and then subjected to a grind etching (JP-A-2006-339302); and

(4) A method in which an outer peripheral portion of a wafer after surface grinding is removed by polishing so as to leave a central portion thereof for making possible the control of etch pits and the omission of grinding and etching of the wafer including orientation flat portion thereof (WO03/098695).

However, all of the above conventional methods (1) to (4) have problems as mentioned below.

In the methods (1) and (2), the terrace portion is damaged by the exfoliation during grinding and micro-dents (etch pits) are formed on the terrace portion by the subsequent etching, which cause a problem that dusts are generated in a device step. Moreover, there is a disadvantage that the beveled shape is deteriorated.

In the method (3), the cost is increased in the formation of the groove, but also there is a fear of damaging the beveled portion.

In the method (4), there is a disadvantage that a special polishing apparatus is necessary.

### SUMMARY OF THE INVENTION

It is an object of the invention to advantageously solve the above problems and to provide a method of producing a bonded wafer in which a bonded wafer having an improved quality of a terrace portion in a wafer for active layer without the occurrence of damages at a beveled portion and the deterioration of the beveled shape can be obtained at low cost without using a special polishing apparatus.

The inventors have made various studies in order to solve the above problems and found that the desired object is advantageously achieved by conducting a terrace processing at a stage of thinning a wafer for active layer by a surface polishing or an etching after a heat treatment for reinforcement followed by the bonding and at the same time serving the terrace processing as a mirror-surface beveling on a wafer for support layer.

That is, it has been found that the terrace processing after the bonding also serves as the mirror-surface beveling on the wafer for support layer, so that (1) it is possible to reduce the cost for the whole process; (2) damages on the beveled surface generated by the bonding step, the heat treatment step for reinforcement, the surface grinding step or the like can be effectively removed to improve the quality; and (3) the terrace processing can be conducted without deteriorating the beveled shape.

The invention is based on the above knowledge.

That is, the summary and construction of the invention are as follows.

1. A method of producing a bonded wafer, which comprises bonding a wafer for active layer to a wafer for support layer, conducting a heat treatment for bonding reinforcement and then thinning the wafer for active layer, wherein the wafer for active layer after the heat treatment for bonding reinforcement is thinned to a thickness of 1 to 20 μm by a surface polishing or an etching and then the wafer for support layer is subjected to both a minor-surface beveling and a terrace processing simultaneously.

2. The method according to the item 1, wherein a wafer not subjected to a mirror-surface beveling is used as at least a wafer for active layer in the wafer for active layer and the wafer for support layer.

According to the invention, it is possible to obtain a bonded wafer having an excellent quality of a terrace portion in a wafer for active layer or being excellent in an in-plane thickness uniformity and less in the voids and further having no deterioration of beveled shape at low cost.

### BRIEF DESCRIPTION OF THE DRAWINGS

FIG. 1A is a diagram illustrating the conventional terrace processing method with a polishing method (Conventional Example 1);

FIG. 1B is a photograph of a wafer processed according to the method of FIG. 1A;

FIG. 2A is a diagram illustrating the conventional terrace processing method with an adhesive tape (Conventional Example 2);

FIG. 2B is a photograph of a wafer processed according to the method of FIG. 2A;

FIG. 2C is a micrograph of a terrace portion of a wafer processed according to the method of FIG. 2A;

FIG. 3A is a diagram illustrating a terrace processing method according to the invention; and

FIG. 3B is a micrograph of a terrace portion of a wafer processed according to the method of FIG. 3A.

### DESCRIPTION OF THE PREFERRED EMBODIMENTS

The invention will be concretely described below.

In the production of the bonded wafer, two silicon wafers, i.e., a wafer for active layer and a wafer for support layer are bonded to each other. The invention is applicable to not only a case that the bonding of both wafers is conducted with an insulating film (oxide film), but also a case that both the wafers are directly bonded without such an insulating film.

Since the usual wafer to be processed is subjected to a minor-surface beveling, it is general to use a mirror-surface beveled wafer as both a wafer for active layer and a wafer for support layer in wafers to be bonded. In the invention, however, the wafer for active layer is subjected to grinding, etching, polishing and the like after the bonding, and the production is possible without using a minor-surface beveled wafer as a wafer for active layer, and hence the cost can be reduced.

In the invention, therefore, a wafer not subjected to the mirror-surface beveling can be used as both a wafer for active layer and a wafer for support layer, or at least as a wafer for active layer.

Subsequently, oxygen ions are implanted into the wafer for active layer for the purpose of forming a polishing stop layer. It is preferable that the oxygen ion implantation is conducted at two stages though it can be conducted at one stage. Also, conditions for the oxygen ion implantation are not particularly limited, and the conventionally well-known conditions may be applied.

The wafer for active layer having an oxygen ion implanted layer formed in its active layer as mentioned above may be subjected to a heat treatment at a temperature of not lower than 1000° C. (pre-annealing). In this case, the heat treatment is conducted in a reducing atmosphere, whereby oxygen implanted in the vicinity of an outermost surface during the oxygen ion implantation can be diffused outward to reduce oxygen concentration, and hence it is possible to suppress the formation of oxygen precipitates in the vicinity of the outermost surface in a heat treatment for bonding reinforcement to more reduce defect density. As the reducing atmosphere is preferable Ar or H₂ or a mixed atmosphere thereof.

Furthermore, in order to form a buried oxide film (BOX), a high-temperature heat treatment may be conducted at a temperature of not lower than 900° C. in a dry oxidizing atmosphere. However, in view of the productivity, it is advantageous that a heat treatment is conducted at a temperature of 800 to 1100° C. in an oxidizing atmosphere containing steam with a high oxidation rate for about 0.5 to 5 hours.

Next, the wafer for active layer is bonded to the wafer for support layer. Prior to the bonding, it is advantageous to conduct a cleaning treatment for suppressing the occurrence of voids due to particles. As the cleaning method, it is sufficient to use a general method of cleaning silicon wafers, which is conventionally well-known.

In order to enhance a bonded strength, it is advantageous that the surface of the silicon wafer before the bonding is previously subjected to an activation treatment with plasma using oxygen, nitrogen, He, H₂, Ar or a mixed atmosphere thereof.

Subsequently, the wafer for active layer is bonded to the wafer for support layer. In this bonding, both the wafers may be bonded to each other with or without an insulating film.

The bonding conditions are not particularly limited, and the conventionally well-known conditions may be applied.

Then, the bonded wafer is subjected to a heat treatment for improving a bonded strength (heat treatment for bonding reinforcement).

The heat treatment for bonding reinforcement is preferable to be conducted at a temperature of not lower than 1100° C. for not less than 1 hour in order to sufficiently improve the bonded strength. The atmosphere is not particularly limited, but is preferably an oxidizing atmosphere forming an oxide film of not less than 150 nm in thickness for protecting the back surface of the bonded wafer at the subsequent grinding step.

Moreover, the surfaces of the wafers to be bonded are exposed in plasma using oxygen, nitrogen or a mixed gas thereof as a raw gas in the bonding so as to improve the bonded strength, and the temperature in the subsequent heat treatment for bonding reinforcement is maintained at a low temperature of not higher than 500° C. for 1 to 5 hours, whereby there can be achieved the bonded strength equal to that in the heat treatment for bonding reinforcement at a temperature of not lower than 1100° C. in the usual bonding. This plasma treatment is effective for the formation of a device such as a backside illumination type CMOS image sensor or the like in such a way that the wafer for active layer is provided with a device and bonded to the wafer for support layer and thereafter a surface of the wafer for active layer opposed to the device-formed surface is thinned instead of the simple bonding of the two wafers. Thus, it can be avoided that the previously-formed device function is broken by the high-temperature heat treatment process of not lower than 500° C.

Subsequently, the bonded wafer is subjected to a grinding treatment so as to leave a part of the wafer for active layer. The grinding on the wafer for active layer in the bonded wafer is carried out by machining. In this grinding, a part of the wafer for active layer is left on the surface side of the oxygen ion implanted layer.

At this moment, it is important that the thickness of the wafer for active layer left is 1 to 20 μm. When the thickness is less than 1 μm, the active layer or the previously-formed device is damaged since the accuracy in the grinding is currently about ±0.5 μm and the mechanical damage by the grinding is about 0.5 μm. While, when it exceeds 20 μm, the burden is put on a treatment for providing a given thickness of the active layer at the subsequent step or a treatment for generally thinning the thickness to 0.05 to 10 μm, which increases the cost.

In the invention, the wafer for support layer is then subjected to a mirror-surface beveling and a terrace processing for removing an unadhered portion of the bonded wafer simultaneously. That is, since the thickness of the wafer for active layer is thinned to 1 to 20 μm, the minor-surface beveling and the terrace processing can be simultaneously applied to the wafer for support layer. This is a greatest feature of the invention. According to this method, there can be obtained a mirror-surface beveled bonded wafer without deteriorating the beveled shape.

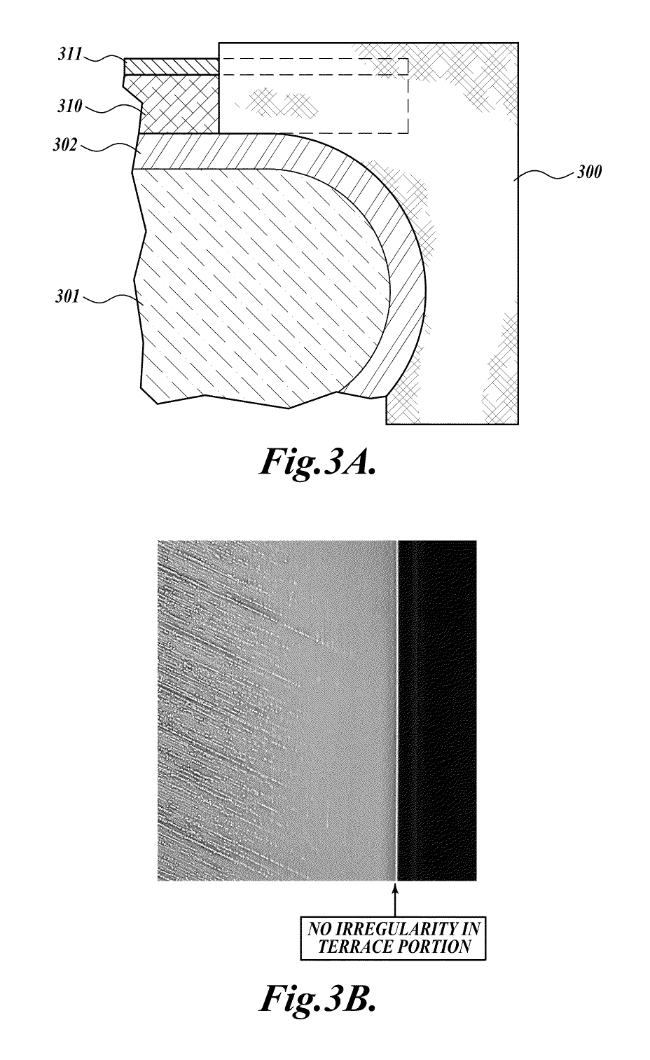

As a concrete method for beveling and terrace processing is preferable a method in which a cloth 300 shaped so as to match with an end face shape of the wafer for support layer is pressed onto the end face of the wafer for support layer to polish the wafer end face at a contact surface therebetween as shown in FIG. 3A. Thus, it is possible to achieve both the mirror-surface beveling and the terrace processing simultaneously.

Moreover, the terrace polishing width is preferable to be smaller for making a device formation area as wide as possible. Concretely, the width is about 1 to 5 mm, preferably not more than 2 mm from the outer periphery of the wafer.

Subsequently, the wafer for active layer is subjected to a polishing or an etching to expose the oxygen ion implanted layer.

As the polishing method (polishing stop method), it is preferable to conduct the grinding while feeding a grinding solution having an abrasive concentration of not more than 1 mass %. As the grinding solution is mentioned an alkaline solution having an abrasive (e.g. silica) concentration of not more than 1 mass %.

As the etching method (etching stop method) is used an alkaline etching solution such as KOH, NaOH or the like.

Moreover, it is also possible to use a combination of the polishing method and the etching method.

The oxygen ion implanted layer is exposed as above and then removed.

As the method for removing the oxygen ion implanted layer, there are an etching process, an oxidation process and the like as mentioned below.

Etching Process

This etching process is a method of removing SiO₂ by immersing in HF solution, wherein the wafer is immersed in a 3-50% HF solution for about 1-30 minutes.

Oxidation Process

This process is composed of a step of forming an oxide film with a given thickness on the exposed surface of the oxygen ion implanted layer and a step of removing the resulting oxide film.

Since it is enough to conduct the oxidation treatment in an oxidizing atmosphere, the treating temperature is not particularly limited, but is preferably 600 to 1100° C. in the oxidizing atmosphere. Also, the thickness of the oxide film is not limited.

The oxide film may be removed by cleaning with HF solution or by etching through annealing with hydrogen gas, Ar gas or a gas containing HF. At this moment, the above oxidation treatment and removal treatment may be conducted plural times. Thus, it is possible to conduct further thinning of the active layer while maintaining the planarized surface roughness.

Thereafter, the surface of the wafer for active layer may be further subjected to a planarization or a thinning treatment, if necessary.

By the aforementioned heat treatment, the surface roughness (RMS) can be rendered into not more than 0.5 nm likewise the case by the polishing method.

Thus, there can be obtained a bonded wafer being excellent in the thickness uniformity and having a planarized surface roughness and being less in the defects.

According to the invention, it is also possible to prepare a bonded wafer by directly bonding silicon wafers having different crystal orientations to each other (e.g., bonding between wafers of 110 crystal and 100 crystal, bonding between wafers of 111 crystal and 100 crystal, or the like).

Moreover, the invention can be applied to bonding of a wafer for active layer having a device formed before the bonding as previously mentioned.

### Example 1

There are provided two silicon wafers of 300 mm in diameter and with a crystal orientation of (100) sliced from a silicon ingot grown by CZ method and doped with boron. This silicon wafer is p-type and has a specific resistance of 1 to 20 Ωcm.

Then, oxygen ion implantation is carried out from the surface of the (100) wafer used as a wafer for active layer among the two wafers at an acceleration voltage of 200 keV. The oxygen ion implantation is conducted at two stages, wherein the first ion implantation is carried out at a substrate temperature of 400° C. and a dose of 1×10¹⁷ atoms/cm² and the second ion implantation is carried out at a substrate temperature of room temperature and a dose of 4×10¹⁵ atoms/cm².

Thereafter, the wafer for active layer is subjected to pre-annealing in an Ar atmosphere at 1100° C. for 12 hours and further to a heat treatment in an oxidizing atmosphere at 950° C. for 2 hours to form a buried oxide film (BOX) having a thickness of 150 nm inside the wafer.

Next, both the wafers are subjected to cleanings of SC1, HF and ozone to remove particles from the surfaces to be bonded and then bonded to each other.

Thereafter, the bonded wafer is subjected to a heat treatment for strongly bonding the bonded interface. The heat treatment is conducted at 1100° C. in an oxidizing atmosphere for 2 hours to form an oxide film having a thickness of about 400 nm on the back surface of the bonded wafer as a back surface protection film for the subsequent processing.

Then, the wafer for active layer in the bonded wafer is ground with a grinding stone of #300 until the thickness left becomes 10 μm from the surface.

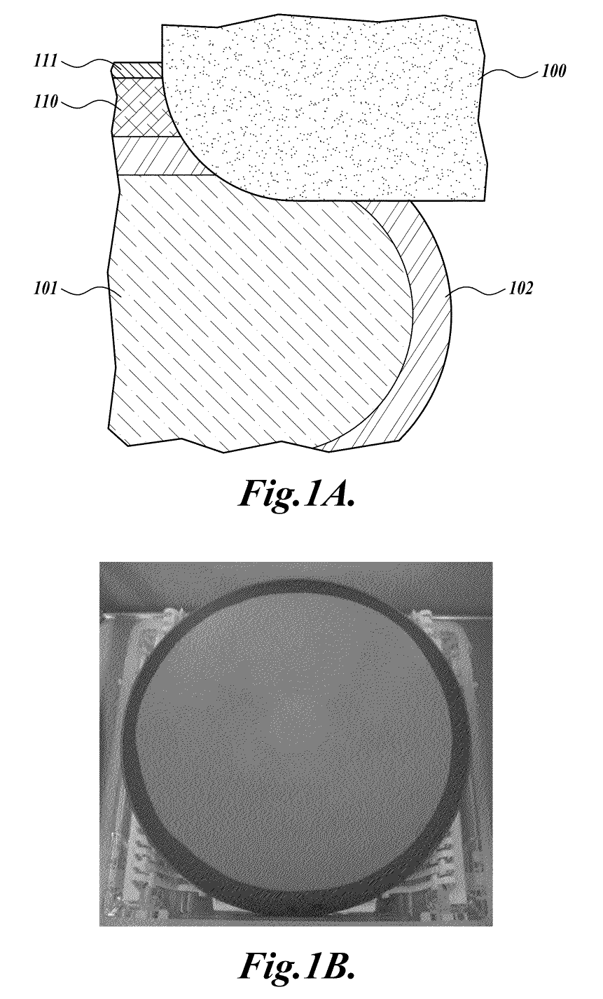

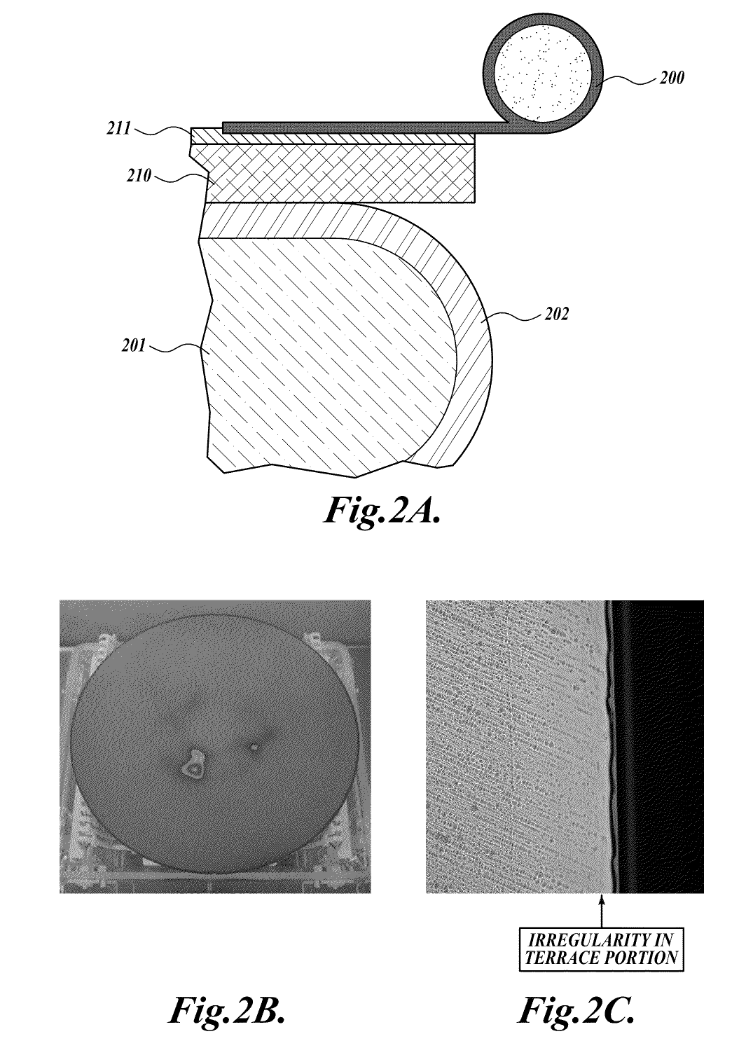

Next, the terrace processing is conducted by methods shown in FIG. 1A, FIG. 2A and FIG. 3A for removing the unadhered portion in the bonded wafer, respectively. In those figures, numeral 100 is a polishing pad, numeral 200 a tape, numeral 300 a cloth, numerals 101, 201, 301 a wafer for support layer, numerals 102, 202, 302 an oxide film, numerals 110, 210, 310 a wafer for active layer and numerals 111, 211, 311 an oxide film.

FIG. 1A shows Conventional Example 1 using a polishing method; FIG. 2A shows Conventional Example 2 using an adhesive tape 200; and FIG. 3A shows the terrace processing according to the invention.

Then, the oxygen ion implanted layer is exposed by polishing the surface of the bonded wafer after the grinding while feeding a polishing solution containing abrasives. As the polishing solution is used an alkaline solution having an abrasive concentration of less than 1 mass %.

Thereafter, the bonded wafer is subjected to a wet oxidation treatment in an oxidizing atmosphere at a temperature of 850° C. for 1 hour. As a result, an oxide film having a given thickness is formed on the exposed surface of the oxygen ion implanted layer, wherein all of Si amorphous layer containing oxygen atoms is changed into an oxide film (SiO₂). Next, the oxide film is removed by HF cleaning (concentration of HF: 20%) for 10 minutes.

In Table 1 are shown the results examined on the terrace appearance and the beveled shape of the thus obtained bonded wafers.

TABLE 1

| | Terrace | | | |
|---|---|---|---|---|
| | processing | Terrace | Appearance of | |
| | method | width | terrace portion | Beveled shape |
| Conventional | Polishing | 20 mm | Terrace width | Damage occurs |
| Example 1 | | | becomes wider. | or beveled |
| | | | | shape changes |
| | | | | due to grinding |
| | | | | and polishing. |
| Conventional | Adhesive tape | 2 mm | Jagged | Mirror-surface |
| Example 2 | | | irregularity is | beveled portion |
| | | | observed over a | is damaged due |
| | | | whole of the | to grinding and |
| | | | examined outer | polishing. |
| | | | peripheral | |
| | | | portion. | |
| Invention | Mirror-surface | 2 mm | Terrace having | Excellent |
| Example | beveling | | constant width | mirror-surface |
| | | | is formed over | beveled portion |
| | | | a full outer | is formed. |
| | | | periphery. | |

As shown in Table 1, in Conventional Examples 1 and 2, the irregularity is formed on the outer peripheral portion of the terrace, or the minor-surface beveled portion is damaged and the deterioration of beveled shape occurs.

On the other hand, when the mirror-surface beveling and terrace processing are conducted simultaneously after the thinning of the wafer for active layer according to the invention, the irregularity at the outer peripheral portion of the terrace and the terrace damages do not occur and no deterioration of the beveled shape is observed, and further the terrace width is as small as 2 mm.

What is claimed is:

1. A method of producing a bonded wafer, which comprises bonding a wafer for active layer to a wafer for support layer, conducting a heat treatment for bonding reinforcement and then thinning the wafer for active layer, wherein the wafer for active layer after the heat treatment for bonding reinforcement is thinned to a thickness of 1 to 20 μm by a surface polishing or an etching and then the wafer for support layer is subjected to both a minor-surface beveling and a terrace processing simultaneously.

2. The method according to claim 1, wherein a wafer not subjected to a mirror-surface beveling is used as at least a wafer for active layer in the wafer for active layer and the wafer for support layer.
